(19) United States
(12) Patent Application Publication
(10) Pub. No.: US 2011/0030930 A1
(43) Pub. Date: Feb. 10, 2011

(54) HEAT DISSIPATION DEVICE

(75) Inventors: FANG-XIANG YU, Shenzhen City (CN); ZHI-YA YANG, Shenzhen City (CN); EN-MING LIANG, Shenzhen City (CN); XIAN-MIN JIN, Shenzhen City (CN); JER-HAUR KUO, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/581,880

(22) Filed: Oct. 20, 2009

(30) Foreign Application Priority Data
Aug. 5, 2009 (CN) 200910305254.3

(51) Int. Cl. H05K 7/20; F28F 7/00

(52) U.S. Cl. 165/121; 165/185; 361/697

(57) ABSTRACT

A heat dissipation device includes a heat sink, an axial fan and a fan cover. The heat sink includes a plurality of fins defining a plurality of longitudinal airflow channels therebetween. The axial fan is mounted on a top side of the heat sink. The axial fan defines an air inlet located adjacent to and communicating with the airflow channels of the heat sink. The fan cover is between the heat sink and the axial fan. The fan cover includes a side plate surrounding a top end of the heat sink to make the axial fan just draw cooling air into the heat sink from a position around a bottom end of the heat sink. The cooling air flows upwardly through the heat sink to the air inlet of the axial fan to thereby take heat away from the heat sink.

### BACKGROUND

1. Technical Field

The disclosure relates to heat dissipation, and particularly to a heat dissipation device for dissipating heat generated by an electronic component.

2. Description of Related Art

Electronic components operating at high speed generate excessive heat which must be removed efficiently to ensure normal operation. Typically, a heat dissipation device attached to the electronic component provides such heat dissipation.

A conventional heat dissipation device includes a heat sink and an axial fan defining an air inlet facing the heat sink. The heat sink has a bottom side contacted an electronic component for absorbing heat therefrom. By this configuration, firstly, the heat generated by the electronic component is conducted to the heat sink. Then the axial fan generates an inhaled airflow flowing through the heat sink to take heat away from the heat sink.

Since the heat sink contacts the electronic component at the bottom side thereof, a bottom end of the heat sink which is adjacent to the bottom side of the heat sink has a higher temperature than other portions of the heat sink. However, the axial fan mounted on a top side of the heat sink mainly draws cooling air into the heat sink from an ambient air adjacent to the air inlet of the axial fan. The air inlet of the axial fan is at a position near a top end of the heat sink. The cooling air flows through the top end of the heat sink to thereby take heat away from the heat sink, whereby the cooling air can not cool the bottom end of the heat sink directly and effectively. Therefore, a heat dissipation efficiency of the heat dissipation device is low.

It is thus desirable to provide a heat dissipation device which can overcome the described limitations.

### BRIEF DESCRIPTION OF THE DRAWINGS

FIG. 1 is an isometric, assembled view of a heat dissipation device according to an exemplary embodiment.

FIG. 2 is an exploded view of the heat dissipation device of FIG. 1, but viewed from a bottom aspect.

### DETAILED DESCRIPTION

Reference will now be made to the drawing figures to describe the present heat dissipation device in detail.

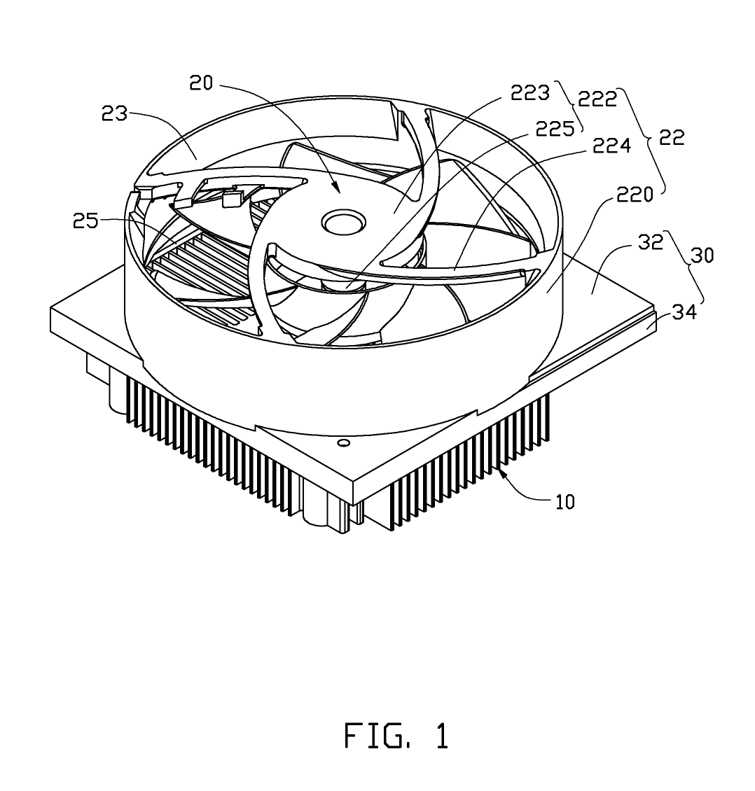

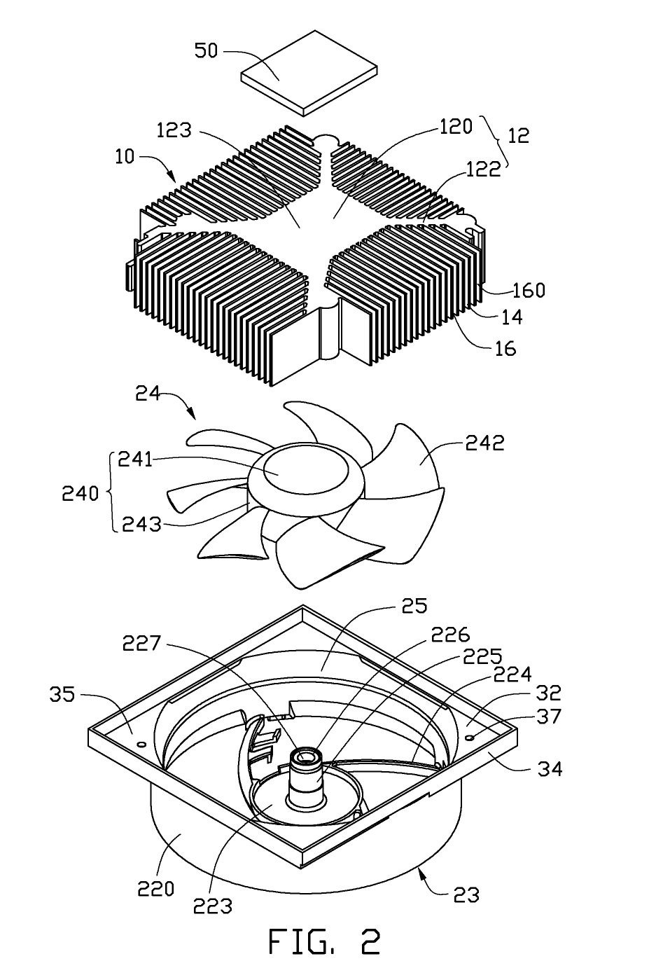

FIGS. 1-2 illustrate a heat dissipation device for dissipating heat generated by an electronic component 50. The heat dissipation device includes a heat sink 10, an axial fan 20 and a fan cover 30.

Referring to FIG. 2, the heat sink 10 in whole has a substantially rectangular configuration. The heat sink 10 includes a main body 12 and a plurality of aluminum extrusion fins 14 extending outwardly from a circumferential side surface of the main body 12. The main body 12 has a quadrangular prism 120 at a center thereof and four protruding portions 122 extending outwardly and diagonally from four corners of the quadrangular prism 120. The quadrangular prism 120 of the main body 12 has an approximately rectangular bottom surface 123 for contacting the electronic component 50 to absorb heat therefrom. The fins 14 extend perpendicularly from four lateral sides of the quadrangular prism 120 of the main body 12, respectively. The fins 14 also extend from two opposite sides of each of the protruding portions 122. A longitudinal airflow channel 16 is formed between each two neighboring fins 14. Each of the airflow channels 16 defines an opening 160 communicated with a corresponding lateral side of the heat sink 10, and communicates top and bottom sides of the heat sink 10 simultaneously.

Referring back to FIG. 1, the axial fan 20 includes a housing 22 and an impeller 24 received in the housing 22. The housing 22 includes an annular sidewall 220 and a base 222 located at a central portion of a top end of the sidewall 220. The sidewall 220 defines an air outlet 23 at the top end and an opposite air inlet 25 at a bottom end. The base 222 is received in the central portion of the air outlet 23. The base 222 includes a base plate 223, a central tube 225 extending downwardly and perpendicularly from a central portion of the base plate 223 towards the air inlet 25 and a plurality of ribs 224 extending radially from an outer periphery of the base plate 223 to connect an inner periphery of the sidewall 220 at the air outlet 23. Referring to FIG. 2, the central tube 225 defines a hole for receiving a bearing 226 therein. The impeller 24 includes a hub 240 and a plurality of blades 242 extending outwardly and radially from a circumference surface of the hub 240. The hub 240 includes a circular top wall 241 and a cylindrical sidewall 243 extending downwardly and perpendicularly from a periphery of the top wall 241. The impeller 24 is mounted to the central tube 225 via a shaft (not shown) extending from a center of the top wall 241 and rotatablely received in a bearing hole 227 of the bearing 226.

The fan cover 30 includes a top plate 32 extending outwardly from a periphery of the sidewall 220 at the air inlet 25 and a side plate 34 extending perpendicularly from a rectangular outer periphery of the top plate 32. The side plate 24 and the top plate 32 cooperatively define a rectangular receiving space 35 therein. The receiving space 35 has a size larger than that of the heat sink 10 for receiving a top end of the heat sink 10 therein. The fan cover 30 and the sidewall 220 of the housing 22 of the axial fan 20 are integrally molded for simplifying a manufacturing method thereof, which can also simplify an assembling process of the heat dissipation device. Two through holes 37 are defined in two diagonally opposite corners of the top plate 32 respectively.

When assembled, the fan cover 30 is mounted on the top end of the heat sink 10 with the axial fan 30 which is invertedly mounted on the central tube 225 of base 222 being located above a top surface of the heat sink 10. The top plate 32 of the fan cover 30 abuts against a periphery portion of the top surface of the heat sink 10, and the air inlet 25 of the axial fan 20 communicates with top ends of the airflow channels 16 simultaneously. The side plate 34 is extended around and covered on the four lateral sides of the top end of the heat sink 10. Two fasteners 40 respectively extend through the through holes 37 of the top plate 32 and engage into the protruding portions 122 of the heat sink 10, for maintaining a firm connection between the axial fan 30 and the heat sink 10.

When used, the bottom surface 123 of the heat sink 123 is attached to the electronic component 50 for absorbing heat therefrom. The impeller 24 of the axial fan 20 rotates rapidly to draw cooling air into the airflow channels 16 and flowing through the heat sink 10 to take heat away from the heat sink 10. Since the fan cover 30 covers on the top end of the heat sink 10, the side plate 34 blocks cooling air around the top end of the heat sink 10 from flowing into the airflow channels 16 of the heat sink 10. The axial fan 20 just draws cooling air into the airflow channels 16 of the heat sink 10 from a position around the bottom end of the heat sink 10. The cooling air then flow upwardly through the airflow channels 16 of the heat sink 10 from a bottom-to-top direction to thereby take more heat away from the heat sink 10.

Due to the bottom surface 123 of the heat sink 10 contacting the electronic component 50 directly, heat generated by the electronic component 50 is firstly conducted to the bottom end of the heat sink 10, and then to other portions of the heat sink 10, which makes the bottom end of the heat sink 10 forms as a heat concentrated area with respect to other portions of the heat sink 10. Since the axial fan 20 draws cooling air around the bottom end of the heat sink 10 into the heat sink 10, the cooling air can directly flow to the heat concentrated area to take heat away from the heat concentrated area of the heat sink 10. Thus, the heat at the heat concentrated area is easily and timely dissipated to ambient air via the axial fan 20, which significantly improves a heat dissipation efficiency of the heat dissipation device. Furthermore, the cooling air around the bottom end of the heat sink 10 flowing into the heat sink 10 has a flowing path within the heat sink 10 longer than the conventional heat dissipation device which mainly draws cooling air around the top end of the heat sink. Thus, the cooling air can take more heat away from the heat sink 10 along its flowing path, and the heat-dissipating efficiency of the heat dissipation device is further increased.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device comprising:
a heat sink comprising a plurality of fins defining a plurality of longitudinal airflow channels therebetween;
an axial fan mounted on a top side of the heat sink, the axial fan defining an air inlet located adjacent to and communicating with the airflow channels of the heat sink and an air outlet located above the air inlet; and
a fan cover between the heat sink and the axial fan, the fan cover comprising a side plate surrounding a top end of the heat sink to make the axial fan just draw cooling air into the heat sink from a position around a bottom end of the heat sink, the cooling air flowing upwardly through the heat sink to the air inlet of the axial fan to thereby take heat away from the heat sink.

2. The heat dissipation device as described in claim 1, wherein the fan cover has an annular sidewall having a top end defining the air outlet and a bottom end defining the air inlet, the fan cover further comprising a top plate extending outwardly from a periphery of the sidewall at the air inlet, the side plate extending perpendicularly from an outer periphery of the top plate towards the heat sink, the top plate and the side plate cooperatively defining a receiving space for receiving the top end of the heat sink therein.

3. The heat dissipation device as described in claim 2, wherein the receiving space has a size larger than that of the top end of the heat sink.

4. The heat dissipation device as described in claim 2, wherein the axial fan comprises a housing and an impeller received in the housing, the housing comprising the annular sidewall.

5. The heat dissipation device as described in claim 4, wherein the housing comprises a base located at a central portion of the air outlet, the base comprising a central tube extending downwards therefrom towards the air inlet, the impeller mounted around the central tube, the impeller having a hub with a circular top wall, a cylindrical sidewall extending downwardly from a periphery of the top wall and a plurality of blades extending radially outwardly from the sidewall of the hub, the impeller being invertedly mounted around the central tube.

6. The heat dissipation device as described in claim 1, wherein the heat sink comprises a main body having a quadrangular prism at a center thereof and four protruding portions extending outwardly and diagonally from four corners thereof, the fins extending outwardly from a circumferential side surface of the main body.

7. The heat dissipation device as described in claim 6, wherein the fan cover defines a plurality of through holes located above the protruding portions of the main body, the fan cover and the heat sink connected together via fasteners extending through the through holes and inserting into the protruding portions.

8. A heat dissipation device comprising:
a heat sink comprising a plurality of fins defining a plurality of airflow channels therebetween;
an axial fan mounted a top side of the heat sink, the axial fan comprising a housing and an impeller received in the housing, the housing defining an air inlet at one end thereof, the air inlet located adjacent to and communicating with the airflow channels of the heat sink; and
a fan cover comprising a top plate extending outwardly from a periphery of the air inlet and a side plate extending from an outer periphery of the top plate towards the heat sink, the top plate and the side plate cooperatively defining a receiving space for receiving a top end of the heat sink therein, the side plate of the fan cover surrounding the top end of the heat sink to block cooling air from flowing into the heat sink via the top end of the heat sink.

9. The heat dissipation device as described in claim 8, wherein the axial fan is invertedly mounted on the top side of the heat sink with the air inlet located adjacent to the heat sink, the housing defining an air outlet at an opposite end and located away from the heat sink.

10. The heat dissipation device as described in claim 9, wherein the axial fan comprises a base located at a central portion of the air outlet, the base comprising a base plate, a central tube extending from the base plate towards the air inlet and a plurality of ribs interconnected between the base plate and a periphery of the air outlet.

11. The heat dissipation device as described in claim 8, wherein the heat sink in whole has a rectangular configuration, the top plate has a rectangular periphery, and the side plate extends perpendicularly from four sides of the periphery of the top plate towards the heat sink.
